(19) United States
(12) Patent Application Publication
(10) Pub. No.: US 2011/0001226 A1
(43) Pub. Date: Jan. 6, 2011

(54) LEAD FRAME, AND ELECTRONIC PART USING THE SAME

(75) Inventors: Toshiyuki YAMADA, Kanagawa (JP); Takehiro KIMURA, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/783,857

(22) Filed: May 20, 2010

(30) Foreign Application Priority Data
Jul. 3, 2009 (JP) 2009-158460

(51) Int. Cl. H01L 23/495

(52) U.S. Cl. 257/676; 257/E23.031

(57) ABSTRACT

A lead frame includes a die pad on which at least one IC chip is mounted, a plurality of leads that electrically connect the IC chip and at least one external element, and a plurality of projections that are formed in at least one edge of the die pad. The projections are used as at least one bonding point that connect with at least one free terminal of the IC chip or as references of positioning when the IC chip is arranged on the die pad.

### INCORPORATION BY REFERENCE

This application is based upon and claims the benefit of priority from Japanese patent application No. 2009-158460, filed on Jul. 3, 2009, the disclosure of which is incorporated herein in its entirety by reference.

### BACKGROUND

1. Field of the Invention

This invention relates to a structure of a lead frame that which an IC (Integrated Circuit) chip is mounted on.

2. Description of Related Art

The lead frames are used as inner wiring of IC chips such as a CPU (Central Processing Unit), memory in various electronic parts. FIG. 9 shows a structure of a conventional general lead frame 101. The lead frame 101 includes a die pad 103 on which an IC chip 102 is mounted and a plurality of leads 104. In this example, each lead 104 is supported by a frame part 111 integrally formed with the die pad 103. The frame part 111 is cut off at the last manufacturing process. The IC chip 102 and external elements (other electronic parts, wiring and the like) are connected electrically by connecting terminals of the IC chip 102 and certain leads 104 by bonding wires 105, and connecting the leads 104 and the external elements.

FIG. 10 shows a process to manufacture electronic parts with lead frame as above. First, the IC chip 102 is arranged and mounted on the die pad 103 of the lead frame 101 (MOUNT PROCESS). Subsequently, the lead frames 104 are connected to terminals of the IC chip 102 by the bonding wires 105 (BONDING PROCESS). FIG. 9 shows a state in which the bonding process is completed. Subsequently, the IC chip 102 and the die pad 103 are sealed by a package 110 made of mold resin or the like (SEALING PROCESS). Last, the frame part 111 outside the package 110 is cut off, and the leads 104 extended outside of the package 110 are formed to have a desired shape (LEAD FORMING PROCESS).

In above-mentioned bonding process, free terminals in the IC chip 102 are processed. The IC chip 102 usually includes a plurality of terminals such as input terminals, output terminals, input and output terminals and the like. Some of these terminals are free terminals connected to nowhere according to the functions of electronic parts and the like. Some of the free terminals need to be processed such as grand connection. One of the processing for the free terminals, includes a method to connect free terminals to space of the die pad 103 through bonding wires. This bonding to the die pad 103 is performed using the space in the die pad 103. This space is shown in FIG. 9 as die pad bonding point 120.

Japanese Unexamined Patent Application Publication No. 3-73560 discloses a structure to turn XY axes of an IC chip with respect to XY axes of a lead frame when the IC chip is mounted on the lead frame. This technique enables to prevent from being concentrated the corners of the IC chip.

### SUMMARY

However, when the conventional lead frame 101 shown in FIG. 9 is used, it is difficult to secure the space for providing the die pad bonding points 120 (see FIG. 9) on the die pad 103 when the chip 112 has an area equal to that of the die pad 103, as shown in FIG. 11. In this case, it is necessary to use a lead frame which is one size larger or newly design a lead frame. Therefore it is difficult to use lead frames having the same standard in common among various types of electronic parts, which increases the manufacturing cost and the manufacturing period. Although FIG. 11 shows the example in which one IC chip 112 having large size is mounted, the same problem occurs similarly when there is no space on the die pad 103 because a plurality of IC chips are mounted on the die pad 103 in a multi-chip module.

Such a problem cannot be solved by Japanese Unexamined Patent Application Publication No. 3-73560. In addition, in Japanese Unexamined Patent Application Publication No. 3-73560, it is difficult to mount the chip with higher accuracy, when a turned chip or a plurality of chips are mounted.

A first exemplary aspect of the present invention is a lead frame that includes a die pad on which at least one IC chip is mounted, a plurality of leads that electrically connect the IC chip and at least one external element, and a plurality of projections that are formed in at least one edge of the die pad.

A second exemplary aspect of the present invention is an electronic part including at least one IC chip mounted on a lead frame, the lead frame including a die pad on which the IC chip is mounted, a plurality of leads that electrically connect the IC chip and at least one external element, and a plurality of projections that are formed in at least one edge of the die pad, in which at least one free terminal of the IC chip or of the external element is electrically connected to the projections.

The projections are used as die pad bonding points, references of positioning of the IC chip and the like. The projections project from edges of the die pad outward. Therefore, the projections can be surely used for the die pad bonding points even if an IC chip has a large area that is equal to the area of the die pad, or a plurality of IC chips are mounted on the die pad. In addition, the projections can be used for the die pad bonding points through the leads, so that the projections can be connected not only to free terminals of the IC chip mounted on the lead frame but also to free terminals of the external element (IC chips mounted on other electronic parts and the like). Furthermore, the projections may be used as references of positioning when the IC chip is mounted on the die pad according to the arrangement, the number, the shape or the like of the projections.

According to the present invention, the space for the die pad bonding is secured surely, even if the IC chip has an area equal to that of the die pad. Therefore, an IC chip having a large area or a number of IC chips can be mounted on the die pad without considering the space for the die pad bonding. In addition, the lead frames having the same standard can be used widely common among various kinds of electronic parts, which reduces the manufacturing cost, the manufacturing period and the like. Furthermore, the IC chip can be mounted with higher accuracy using the projections as references for positioning when the IC chip is mounted on the die pad.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a view showing a structure of a lead frame of a first exemplary embodiment of the present inventions;

FIG. 2 is a partially enlarged view showing clearance among edges, projections and leads in the lead frame of the first exemplary embodiment;

FIG. 3 is a view showing a state of the lead frame after a mount process in a first example of the first exemplary embodiment;

FIG. 4 is a view showing a state of the lead frame after a bonding process in the first example;

FIG. 5 is a view showing a state of the lead frame after the mount process in a second example of the first exemplary embodiment;

FIG. 6 is a view showing a state of the lead frame after the bonding process in the second example;

FIG. 7 is a view showing a state of the lead frame after the mount process in a third example of the first exemplary embodiment;

FIG. 8 is a view showing a state of the lead frame after the bonding process in the third example;

FIG. 9 is a view showing a structure and a usage state of the lead frame of one example of a background art;

FIG. 10 is a view showing a general process to produce an

FIG. 11 is a view showing a usage state of the lead frame of another example of the background art.

### DETAILED DESCRIPTION OF THE EXEMPLARY EMBODIMENTS

### First Exemplary Embodiment

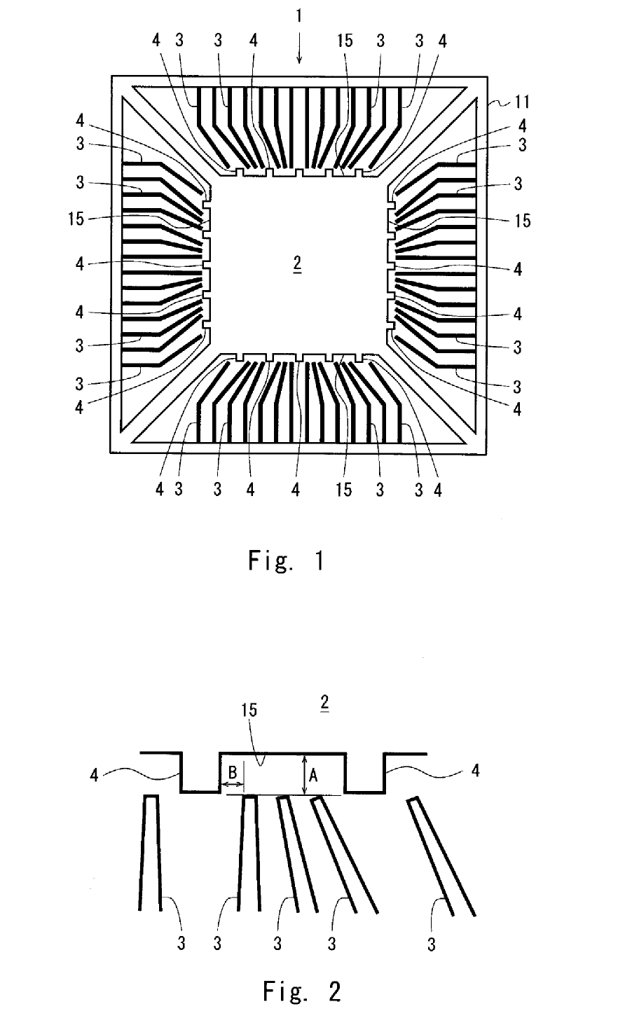

In the following, a first exemplary embodiment of the present invention is explained with reference to the drawings. FIG. 1 is a view showing a structure of a lead frame 1 of the first exemplary embodiment. The lead frame 1 is used as inner wiring of various electronic parts. The lead frame 1 is a sheet made of copper alloy, iron-nickel alloy or the like. The lead frame 1 includes a die pad 2, leads 3, and projections 4.

The die pad 2 is an area in which at least one IC chip is arranged and fixed. In this exemplary embodiment, the die pad 2 is located substantially at the center of the whole lead frame 1 and has a square shape.

The leads 3 are comb-shaped parts radially extended to surround the die pad 2. The leads 3 electrically connect the IC chip mounted on the die pad 2 and external elements (IC chips mounted on other electronic parts, wiring and the like). Each of the leads 3 is supported by a frame part 11 integrally formed with the die pad 2. Between each of the leads 3 and the die pad 2, predetermined clearance is secured. This clearance will be described later.

The projections 4 are formed in edges 15 of the die pad 2. Each of the projections 4 projects from the edges 15 toward the leads 3. In this exemplary embodiment, each of the edges 15 has five projections 4 arranged at equal distances. The projections 4 are used as die pad bonding points, and also used as references of positioning when the IC chip is mounted on the die pad 2.

FIG. 2 is a partially enlarged view showing clearance among the edges 15, the projections 4, and the leads 3. Distance A is secured between tips of the leads 3 and the edges 15. Distance B is secured between the tips of the leads 3 and the projections 4. The distance A and B are set in consideration of thickness of a blade of a die that is used to produce the lead frame 1 by press working. The distance A and B may have the same value.

### First Example

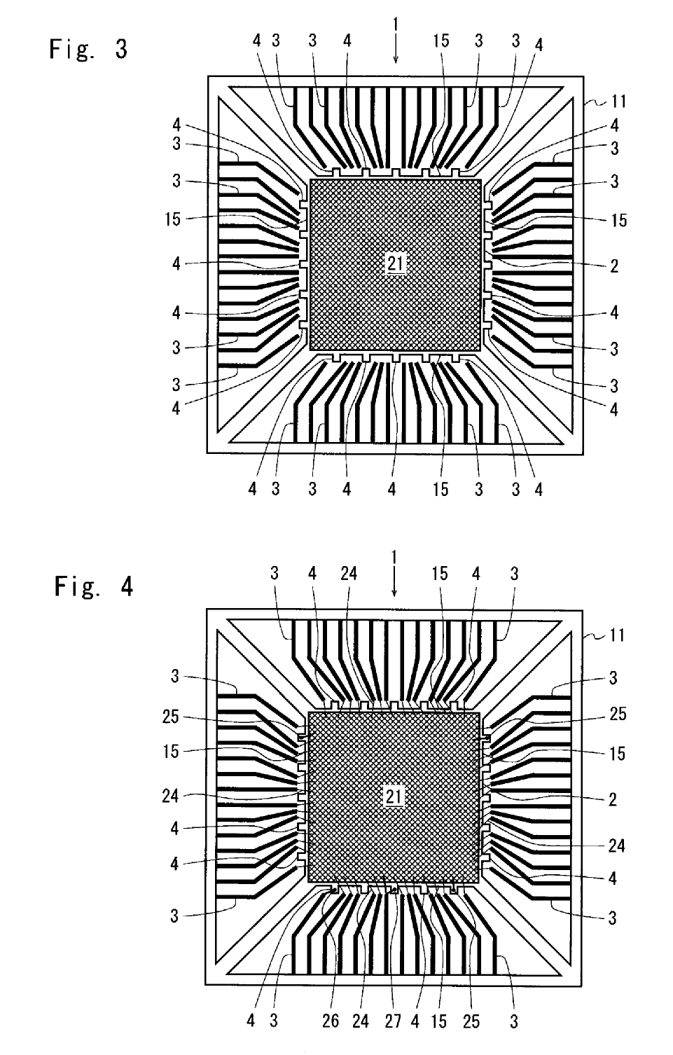

FIG. 3 and FIG. 4 each shows a usage state of the lead frame 1. FIG. 3 shows a state (after a mount process) in which an IC chip 21 is arranged on the die pad 2. FIG. 4 shows a state (after a bonding process) in which the leads 3 and the terminals of the IC chip 21 arranged on the die pad 2 are connected by bonding wires 24.

The IC chip 21 has an area equal to that of the die pad 2 as shown in FIG. 3. Therefore there is little space on the die pad 2. However, space for the die pad bonding is secured because the projections 4 project from the edges 15 of the die pad 2 outward.

In this example, as shown in FIG. 4, some of the projections 4 are used as first to third die pad bonding points 25, 26, 27. The first die pad bonding point 25 connects to a free terminal of the IC chip 21 mounted on the die pad 2. The second die pad bonding point 26 connects to a free terminal of an IC chip (another IC chip) mounted on another electronic part through the lead 3. The third die pad bonding point 27 connects to the free terminals of the IC chip 21 and another IC chip.

In this way, the space for the die pad bonding is secured surely by forming the projections 4 even if the IC chip 21 has an area equal to that of the die pad 2. Therefore, an IC chip having a large area or a number of IC chips can be mounted on the die pad 2 without considering the space for the die pad bonding. In addition, the lead frames 1 having the same standard can be used widely in common among various kinds of electronic parts, which reduces the manufacturing cost, the manufacturing period and the like.

### Second Example

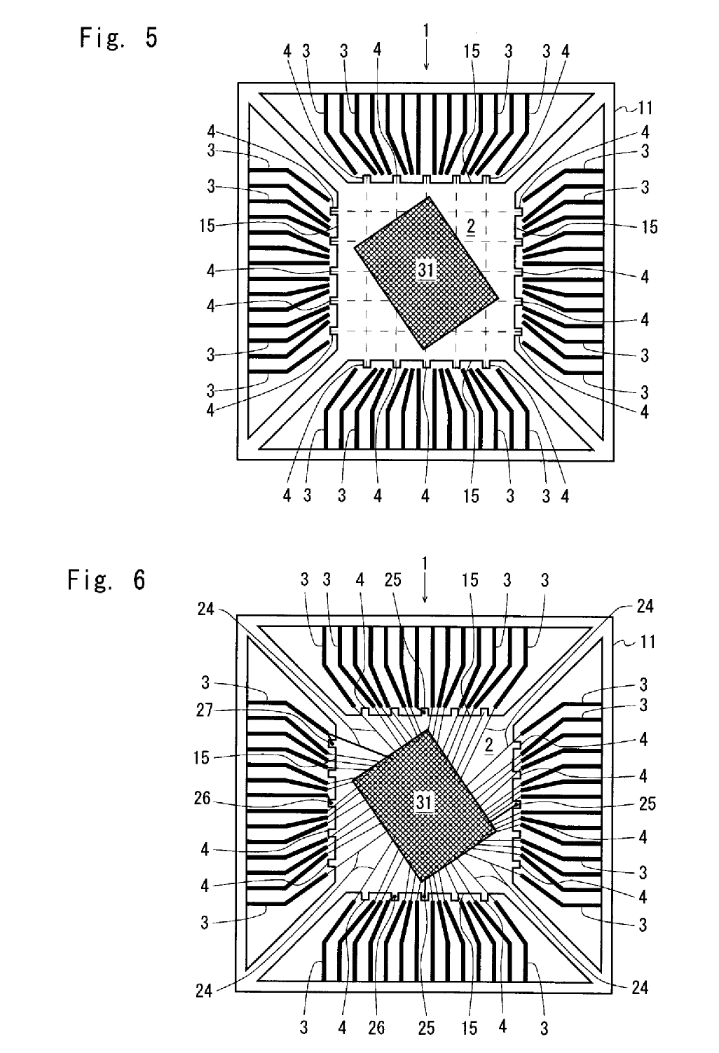

FIG. 5 and FIG. 6 each shows another usage state of the lead frame 1. FIG. 5 shows a state (after a mount process) in which an IC chip 31 is arranged on the die pad 2. FIG. 6 shows a state (after a bonding process) in which the leads 3 and the terminals of the IC chip 31 arranged on the die pad 2 are connected by the bonding wires 24.

As shown in FIG. 5, the IC chip 31 of this example has a comparatively small area with respect to the area of the die pad 2. In this case, it is difficult to mount the IC chip 31 with high accuracy. However, the projections 4 can be used as references of positioning, because each of the edges 15 has equal number of projections 4 at equal distances in the first exemplary embodiment.

In addition, as shown in FIG. 6, some of the projections 4 are used as the first to third die pad bonding points 25, 26, 27. The first die pad bonding point 25 connects to a free terminal of the IC chip 31 mounted on the die pad 2. The second die pad bonding point 26 connects to a free terminal of an IC chip (another IC chip) mounted on another electronic part through the lead 3. The third die pad bonding point 27 connects to free terminals of the IC chip 31 and another IC chip.

In this way, the projections 4 are also effective to improve accuracy of the positioning when an IC chip having a comparatively small area with respect to the die pad 2 is mounted.

### Third Example

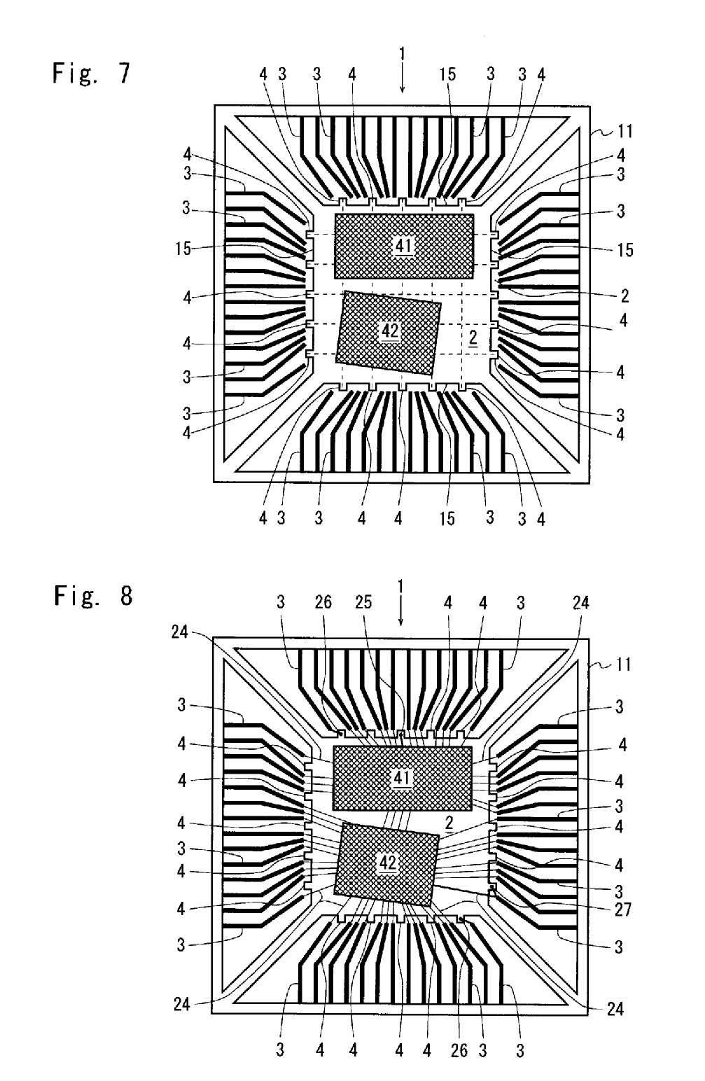

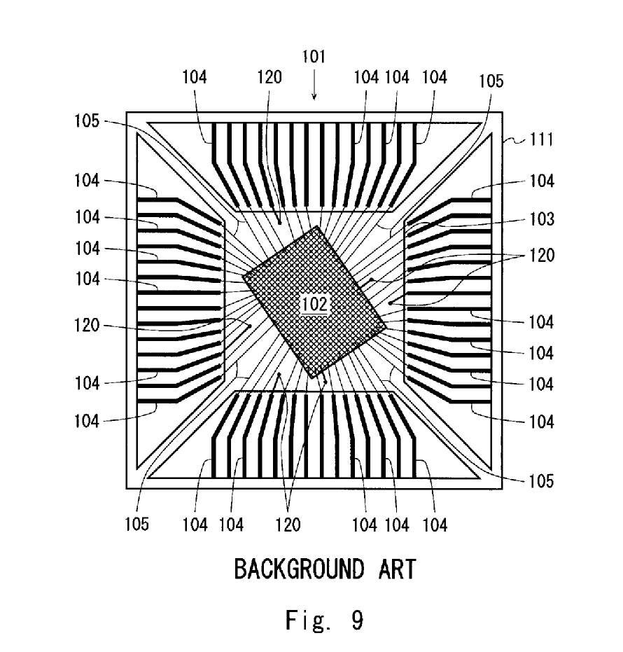

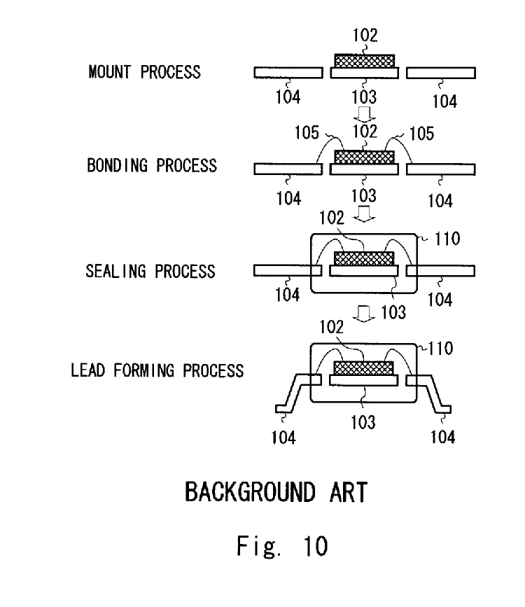

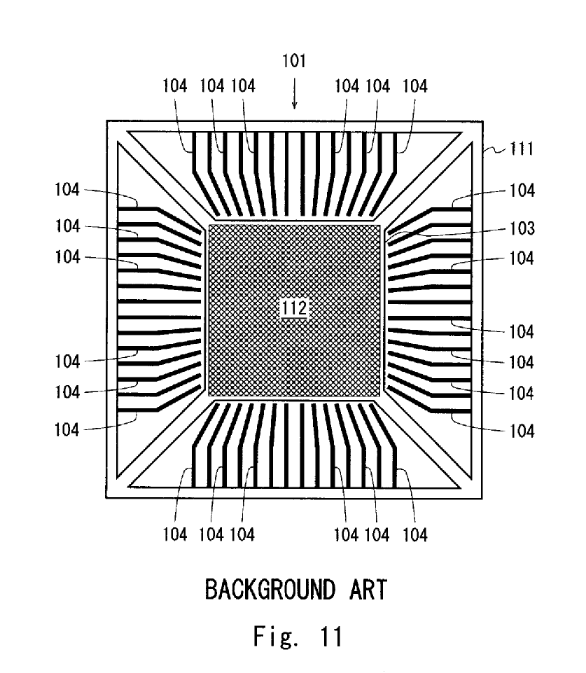

FIG. 7 and FIG. 8 each shows another usage state of the lead frame 1. FIG. 7 shows a state (after a mount process) in which IC chips 41, 42 are arranged on the die pad 2. FIG. 8 shows a state (after a bonding process) in which the leads 3 and the terminals of the IC chips 41, 42 arranged on the die pad 2 are connected by the bonding wires 24.

As shown FIG. 7, in this example, two IC chips 41, 42 are mounted. Occupation area of each of the IC chips 41, 42 is comparatively small with respect to the area of the die pad 2. However, the whole occupation area of both chips 41, 42 is comparatively large with respect to the area of the die pad 2.

In this case, it is difficult to mount the IC chips 41, 42 with high accuracy, and to find the space for the die pad bonding. The problem of the mounting position is solved using the position of the projections 4 as references, as is similar to the second example. Moreover, as shown in FIG. 8, the problem of the space for the die pad bonding is solved and using some of the projections 4 as the first to third die pad bonding points 25, 26, 27, as is similar to the first and second examples.

While the invention has been described in terms of the exemplary embodiment and the examples, those skilled in the art will recognize that the invention can be practiced with various modifications within the spirit and scope of the appended claims and the invention is not limited to the examples described above.

Further, the examples can be combined as desirable by one of ordinary skill in the art.

Furthermore, the scope of the claims is not limited by the exemplary embodiment and the examples described above.

Furthermore, it is noted that, Applicant's intent is to encompass equivalents of all claim elements, even if amended later during prosecution.

What is claimed is:

1. A lead frame comprising:
a die pad on which at least one IC chip is mounted;
a plurality of leads that electrically connect the IC chip and at least one external element; and
a plurality of projections that are formed in at least one edge of the die pad.

2. The lead frame according to claim 1, wherein the projections are used as at least one bonding point that connect with at least one free terminal of the IC chip or the external element.

3. The lead frame according to claim 1, wherein the projections are used as references of positioning when the IC chip is arranged on the die pad.

4. The lead frame according to claim 1, wherein the plurality of projections are arranged at equal distances in each of the edges.

5. The lead frame according to claim 1, wherein each of the leads has such a shape that predetermined clearance can be secured between the leads and the edges and between the leads and the projections.

6. An electronic part comprising at least one IC chip mounted on a lead frame, the lead frame comprising:
a die pad on which the IC chip is mounted;
a plurality of leads that electrically connect the IC chip and at least one external element; and
a plurality of projections that are formed in at least one edge of the die pad, wherein
at least one free terminal of the IC chip or of the external element is electrically connected to the projections.
